(19) United States
(12) Patent Application Publication
(10) Pub. No.: US 2006/0240344 A1
(43) Pub. Date: Oct. 26, 2006

(54) Method of manufacture of polymer arrays

(75) Inventors: John V. Cole, Los Gatos, CA (US); Mark O. Trulson, San Jose, CA (US)

Correspondence Address: AFFYMETRIX, INC;ATTN: CHIEF IP COUNSEL, LEGAL DEPT., 3420 CENTRAL EXPRESSWAY, SANTA CLARA, CA, 95051, US

(73) Assignee: Affymetrix, INC., Santa Clara, CA (US)

(21) Appl. No.: 11/400,343

(22) Filed: Apr. 7, 2006

Related U.S. Application Data
(60) Provisional application No. 60/673,467, filed on Apr. 20, 2005.

(51) Int. Cl. G03F 9/00; G03F 7/20

(52) U.S. Cl. 430/22; 430/311

(57) ABSTRACT

The present invention provides methods to reduce bleed-over of transmitted light through a photolithographic mask during photolysis by reducing the gap between the mask and the substrate upon which photolithography is being performed. In a preferred embodiment of the invention, a leveling method in combination with a compressed gas is used to significantly reduce the gap during the photolithography process and to provide increased photolithographic contrast and resolution.

### CROSS-REFERENCES TO RELATED APPLICATIONS

This application claims priority to U.S. Provisional Application No. 60/673,467, filed Apr. 20, 2005, which is incorporated by reference herein.

### FIELD OF INVENTION

The present invention provides methods for the photolithographic fabrication of high density polymer arrays. According to an aspect of the present invention, the provided methods relate to reducing bleed-over of light transmitted through a photolithographic mask. More particularly, the methods disclosed reduces bleed-over by reducing the gap between a mask and a substrate during a photolysis step.

### BACKGROUND OF THE INVENTION

Methods have been developed for producing high density arrays of polymer sequences on solid substrates. These high density arrays of polymer sequences have wide ranging applications and are of substantial importance to the pharmaceutical, biotechnology and medical industries. For example, the arrays may be used in screening large numbers of molecules for biological activity, i.e., receptor binding capability. Alternatively, arrays of oligonucleotide probes can be used to identify mutations in known sequences, as well as in methods for de novo sequencing of target nucleic acids.

In one technology for fabricating arrays, light is directed to selected regions of a substrate to remove protecting groups from the selected regions of the substrate. Thereafter, selected molecules are coupled to the substrate at selected regions, followed by additional irradiation and coupling steps. By activating selected regions of the substrate and coupling selected monomers in precise order, one can synthesize an array of molecules having any number of different sequences, where each sequence is in a distinct, known location on the surface of the substrate.

### SUMMARY OF THE INVENTION

In accordance with one aspect of the present invention, novel processes are provided for the efficient preparation of arrays of polymer sequences wherein each array includes a plurality of different, positionally distinct polymer sequences having known monomer sequences. In one embodiment, the present invention provides a method for reducing bleed-over of light during the fabrication of an array of polymers on a substrate using light-directed synthesis. The method provides an alignment step of the apertures of a mask to the features of the support. After the alignment step, the support is juxtaposed to the mask to create a first gap which is the distance between the surfaces of the mask and the substrate. After the alignment step, the method provides a compressing step of the substrate against the mask to form a second gap which is smaller than the first gap. A light of a predetermined wavelength is transmitted through the apertures of the mask to illuminate areas on the substrate to remove photolabile protecting groups and to expose the plurality of reactive groups.

In accordance with another aspect of the present invention, the method further includes the substrate being coupled with monomers which have reactive groups protected by a photolabile protecting group. The aligning, juxtaposing, compressing, transmitting and coupling steps are repeated until the desired array is generated.

In another embodiment of the present invention, the compressing step further includes the steps of: providing a first amount of force against the support to obtain equalized force measurements to a predetermined target value; measuring a first set of force measurements of the first amount of force; correcting the first set of force measurements by using an algorithm that equalizes the first set of force measurements to the predetermined target value; applying a second amount of force based on the correction step of the algorithm against the support to obtain a second set of force measurements; and repeating the measuring, correcting and applying steps to obtain the equalized force to the predetermined target value.

The present invention also provides a method for forming an array of polymers on a substrate using light-directed synthesis wherein the compression step further includes applying a gas to the underside of the substrate to compress the substrate against the mask during the light exposure step of the photolysis process.

### BRIEF DESCRIPTION OF THE DRAWINGS

The accompanying drawings, which are incorporated in and form a part of this specification, illustrate embodiments of the invention and, together with the description, serve to explain the principles of the invention:

FIGS. 1A to 1G show schematic diagrams illustrating how the leveling and the gas compressing methods are used to compress a wafer against a mask during the photolysis process. FIG. 1A shows the mask and wafer being held to the upper chuck and lower chuck respectively by using vacuum. FIG. 1B shows the step where the wafer is placed into contact with the mask. FIG. 1C shows the step where the leveling and gas compressing methods are applied to compress the wafer against the mask. FIG. 1D shows the step where the light is transmitted through the mask onto the wafer while the wafer is compressed against the mask. FIG. 1E shows the step where the substrate and mask are back in contact. FIG. 1F shows the step where the vacuum from the lower chuck is turned back on to hold the substrate against the lower chuck. FIG. 1G shows the step where the chucks are moved apart to make the substrate accessible.

FIG. 2 shows a scanning electron microscope (SEM) image of a wafer synthesized using the standard manufacturing synthesis process.

FIG. 3 shows a chart of the modulation transfer function (MTF) results from wafers synthesized using the standard manufacturing synthesis process with various print gaps.

FIG. 4 shows the load cell force results of the three load cells from applying various leveling methods to a wafer juxtaposed to a mask.

FIG. 5 shows the gap profile of the wafer and mask from a wafer synthesized using the standard manufacturing synthesis process.

FIG. 6 shows the gap profile of the wafer and mask from a wafer synthesized using the standard manufacturing synthesis process and a leveling method.

FIG. 7 shows the gap profile of the wafer and mask from a wafer synthesized using the standard manufacturing synthesis process and a combination of a leveling and a gas compressing method.

FIG. 8 shows SEM images from a wafer synthesized using the standard manufacturing synthesis process and a combination of a leveling and a gas compressing method. FIGS. 8A and 8B show the results from hybridized 1 μm lanes and 1 μm dots respectively.

### DETAILED DESCRIPTION OF THE INVENTION

a) General

The present invention has many preferred embodiments and relies on many patents, applications and other references for details known to those of the art. Therefore, when a patent, application, or other reference is cited or repeated below, it should be understood that it is incorporated by reference in its entirety for all purposes as well as for the proposition that is recited.

As used in this application, the singular form “a,” “an,” and “the” include plural references unless the context clearly dictates otherwise. For example, the term “an agent” includes a plurality of agents, including mixtures thereof.

An individual is not limited to a human being, but may also be other organisms including, but not limited to, mammals, plants, bacteria, or cells derived from any of the above.

Throughout this disclosure, various aspects of this invention can be presented in a range format. It should be understood that the description in range format is merely for convenience and brevity and should not be construed as an inflexible limitation on the scope of the invention. Accordingly, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 3, 4, 5, and 6. This applies regardless of the breadth of the range.

The practice of the present invention may employ, unless otherwise indicated, conventional techniques and descriptions of organic chemistry, polymer technology, molecular biology (including recombinant techniques), cell biology, biochemistry, and immunology, which are within the skill of the art. Such conventional techniques include polymer array synthesis, hybridization, ligation, and detection of hybridization using a label. Specific illustrations of suitable techniques can be had by reference to the example herein below. However, other equivalent conventional procedures can, of course, also be used. Such conventional techniques and descriptions can be found in standard laboratory manuals such as Genome Analysis: A Laboratory Manual Series (Vols. I-IV), Using Antibodies: A Laboratory Manual, Cells: A Laboratory Manual, PCR Primer: A Laboratory Manual, and Molecular Cloning: A Laboratory Manual (all from Cold Spring Harbor Laboratory Press), Stryer, L. (1995) Biochemistry (4th Ed.) Freeman, New York, Gait, “Oligonucleotide Synthesis: A Practical Approach” 1984, IRL Press, London, Nelson and Cox (2000), Lehninger, Principles of Biochemistry 3^{rd} Ed., W. H. Freeman Pub., New York, N.Y. and Berg et al. (2002) Biochemistry, 5^{th} Ed., W. H. Freeman Pub., New York, N.Y., all of which are herein incorporated in their entirety by reference for all purposes.

The present invention can employ solid substrates, including arrays in some preferred embodiments. Methods and techniques applicable to polymer (including protein) array synthesis have been described in U.S. Ser. No. 09/536,841, WO 00/58516, U.S. Pat. Nos. 5,143,854, 5,242,974, 5,252,743, 5,324,633, 5,384,261, 5,405,783, 5,424,186, 5,451,683, 5,482,867, 5,491,074, 5,527,681, 5,550,215, 5,571,639, 5,578,832, 5,593,839, 5,599,695, 5,624,711, 5,631,734, 5,795,716, 5,831,070, 5,837,832, 5,856,101, 5,858,659, 5,936,324, 5,968,740, 5,974,164, 5,981,185, 5,981,956, 6,025,601, 6,033,860, 6,040,193, 6,090,555, 6,136,269, 6,269,846 and 6,428,752, in PCT Applications Nos. PCT/US99/00730 (International Publication No. WO 99/36760) and PCT/US01/04285 (International Publication No. WO 01/58593), which are all incorporated herein by reference in their entirety for all purposes.

Patents that describe synthesis techniques in specific embodiments include U.S. Pat. Nos. 5,412,087, 6,147,205, 6,262,216, 6,310,189, 5,889,165, and 5,959,098. Nucleic acid arrays are described in many of the above patents, but the same techniques are applied to polypeptide arrays.

Nucleic acid arrays that are useful in the present invention include those that are commercially available from Affymetrix (Santa Clara, Calif.) under the brand name GeneChip®. Example arrays are shown on the website at affymetrix.com.

The present invention also contemplates many uses for polymers attached to solid substrates. These uses include gene expression monitoring, profiling, library screening, genotyping and diagnostics. Gene expression monitoring and profiling methods can be shown in U.S. Pat. Nos. 5,800,992, 6,013,449, 6,020,135, 6,033,860, 6,040,138, 6,177,248 and 6,309,822. Genotyping and uses therefore are shown in U.S. Ser. Nos. 10/442,021, 10/013,598 (U.S. Patent Application Publication 20030036069), and U.S. Pat. Nos. 5,856,092, 6,300,063, 5,858,659, 6,284,460, 6,361,947, 6,368,799 and 6,333,179. Other uses are embodied in U.S. Pat. Nos. 5,871,928, 5,902,723, 6,045,996, 5,541,061, and 6,197,506.

The present invention also contemplates sample preparation methods in certain preferred embodiments. Prior to or concurrent with genotyping, the genomic sample may be amplified by a variety of mechanisms, some of which may employ PCR. See, for example, PCR Technology: Principles and Applications for DNA Amplification (Ed. H. A. Erlich, Freeman Press, NY, N.Y., 1992); PCR Protocols: A Guide to Methods and Applications (Eds. Innis, et al., Academic Press, San Diego, Calif., 1990); Mattila et al., Nucleic Acids Res. 19, 4967 (1991); Eckert et al., PCR Methods and Applications 1, 17 (1991); PCR (Eds. McPherson et al., IRL Press, Oxford); and U.S. Pat. Nos. 4,683,202, 4,683,195, 4,800,159, 4,965,188, and 5,333,675, each of which is incorporated herein by reference in their entireties for all purposes. The sample may be amplified on the array. See, for example, U.S. Pat. No. 6,300,070 and U.S. Ser. No. 09/513,300, which are incorporated herein by reference.

Other suitable amplification methods include the ligase chain reaction (LCR) (for example, Wu and Wallace, Genomics 4, 560 (1989), Landegren et al., Science 241, 1077 (1988) and Barringer et al. Gene 89:117 (1990)), transcription amplification (Kwoh et al., Proc. Natl. Acad. Sci. USA 86, 1173 (1989) and WO88/10315), self-sustained sequence replication (Guatelli et al., Proc. Nat. Acad. Sci. USA, 87, 1874 (1990) and WO90/06995), selective amplification of target polynucleotide sequences (U.S. Pat. No. 6,410,276), consensus sequence primed polymerase chain reaction (CP-PCR) (U.S. Pat. No. 4,437,975), arbitrarily primed polymerase chain reaction (AP-PCR) (U.S. Pat. Nos. 5,413,909, 5,861,245) and nucleic acid based sequence amplification (NABSA). (See, U.S. Pat. Nos. 5,409,818, 5,554,517, and 6,063,603, each of which is incorporated herein by reference). Other amplification methods that may be used are described in U.S. Pat. Nos. 5,242,794, 5,494,810, 4,988,617 and in U.S. Ser. No. 09/854,317, each of which is incorporated herein by reference.

Additional methods of sample preparation and techniques for reducing the complexity of a nucleic sample are described in Dong et al., Genome Research 11, 1418 (2001), in U.S. Pat. No. 6,361,947, 6,391,592 and U.S. Ser. Nos. 09/916,135, 09/920,491 (U.S. Patent Application Publication 20030096235), 09/910,292 (U.S. Patent Application Publication 20030082543), and 10/013,598.

Methods for conducting polynucleotide hybridization assays have been well developed in the art. Hybridization assay procedures and conditions will vary depending on the application and are selected in accordance with the general binding methods known including those referred to in: Maniatis et al. Molecular Cloning: A Laboratory Manual (2^{nd} Ed. Cold Spring Harbor, N.Y, 1989); Berger and Kimmel Methods in Enzymology, Vol. 152, Guide to Molecular Cloning Techniques (Academic Press, Inc., San Diego, Calif., 1987); Young and Davis, P.N.A.S, 80: 1194 (1983). Methods and apparatus for carrying out repeated and controlled hybridization reactions have been described in U.S. Pat. Nos. 5,871,928, 5,874,219, 6,045,996 and 6,386,749, 6,391,623 each of which are incorporated herein by reference

The present invention also contemplates signal detection of hybridization between ligands in certain preferred embodiments. See U.S. Pat. Nos. 5,143,854, 5,578,832, 5,631,734, 5,834,758, 5,936,324, 5,981,956, 6,025,601, 6,141,096, 6,185,030, 6,201,639, 6,218,803, and 6,225,625 in U.S. Ser. No. 10/389,194 and in PCT Application PCT/US99/06097 (published as WO99/47964), each of which also is hereby incorporated by reference in its entirety for all purposes.

Methods and apparatus for signal detection and processing of intensity data are disclosed in, for example, U.S. Pat. Nos. 5,143,854, 5,547,839, 5,578,832, 5,631,734, 5,800,992, 5,834,758, 5,856,092, 5,902,723, 5,936,324, 5,981,956, 6,025,601, 6,090,555, 6,141,096, 6,185,030, 6,201,639; 6,218,803; and 6,225,625, in U.S. Ser. Nos. 10/389,194, 60/493,495 and in PCT Application PCT/US99/06097 (published as WO99/47964), each of which also is hereby incorporated by reference in its entirety for all purposes.

The practice of the present invention may also employ conventional biology methods, software and systems. Computer software products of the invention typically include computer readable medium having computer-executable instructions for performing the logic steps of the method of the invention. Suitable computer readable medium include floppy disk, CD-ROM/DVD/DVD-ROM, hard-disk drive, flash memory, ROM/RAM, magnetic tapes, etc. The computer-executable instructions may be written in a suitable computer language or combination of several languages. Basic computational biology methods are described in, for example, Setubal and Meidanis et al., Introduction to Computational Biology Methods (PWS Publishing Company, Boston, 1997); Salzberg, Searles, Kasif, (Ed.), Computational Methods in Molecular Biology, (Elsevier, Amsterdam, 1998); Rashidi and Buehler, Bioinformatics Basics: Application in Biological Science and Medicine (CRC Press, London, 2000) and Ouelette and Bzevanis Bioinformatics: A Practical Guide for Analysis of Gene and Proteins (Wiley & Sons, Inc., 2^{nd} ed., 2001). See U.S. Pat. No. 6,420,108.

The present invention may also make use of various computer program products and software for a variety of purposes, such as probe design, management of data, analysis, and instrument operation. See, U.S. Pat. Nos. 5,593,839, 5,795,716, 5,733,729, 5,974,164, 6,066,454, 6,090,555, 6,185,561, 6,188,783, 6,223,127, 6,229,911 and 6,308,170.

Additionally, the present invention may have preferred embodiments that include methods for providing genetic information over networks such as the Internet as shown in U.S. Ser. Nos. 10/197,621, 10/063,559 (United States Publication No. 20020183936), 10/065,856, 10/065,868, 10/328,818, 10/328,872, 10/423,403, and 60/482,389.

b) Definitions

The term “array” as used herein refers to an intentionally created collection of molecules which can be prepared either synthetically or biosynthetically. The molecules in the array can be identical or different from each other.

The term “feature” as used herein refers to a predefined area for formation of a selected polymer.

The term “juxtaposing” as used herein refers to the act of positioning two objects close together wherein a surface of one object is physically touching a surface of the other object.

The term “mask” as used herein refers to a substantially flat surface having substantially transparent regions and substantially opaque regions.

The term “monomer” as used herein refers to any member of the set of molecules that can be joined together to form an oligomer or polymer, for example, the four different nucleotides, which are adenine (A), thymine (T), guanine (G), and cytosine (C).

The term “photolabile protecting group” as used herein refers to a material which is chemically bound to a reactive functional group on a monomer unit or polymer and which a protective group may be removed upon selective exposure to an activator such as a chemical activator, or another activator, such as electromagnetic radiation or light, especially ultraviolet and visible light.

The term “solid support” as used herein refers to a support whose surface is substantially flat, although in some embodiments it may be desirable to physically separate synthesis regions for different compounds with, for example, wells, raised regions, pins, etched trenches, or the like.

The term “substrate” as used herein refers to a material or group of materials having a rigid or semi-rigid surface.

The term “wafer” as used herein refers to a substrate having a surface to which a plurality of arrays is bound.

Bleed-Over Reduction Methods

In seeking to reduce feature size, it is important to maximize the contrast the regions of the substrate exposed to light during a given photolysis step, and between those regions which remain dark or are not exposed. One cause of reduced contrast is “bleed-over” from exposed regions to non-exposed regions during a particular photolysis step. The causes of light bleed-over are poor light collimation and diffraction. Some of the light is diffracted onto the surface of the substrate away from the edge, into unintended regions, a result of the imperfect contact of the substrate to the mask.

According to an aspect of the present invention, additional compression of the mask to the substrate minimizes this light diffraction and thus improves the contrast by reducing the light bleed-over. In a preferred embodiment of the present invention, a leveling method and a gas compressing method are provided to reduce light bleed-over. A leveling method is a method that uses an algorithm to provide equalized distributed force across a device that holds the wafer against a mask. A gas compressing method involves using a gas to compress the substrate against the mask such that the substrate surface conforms to the surface of the mask.

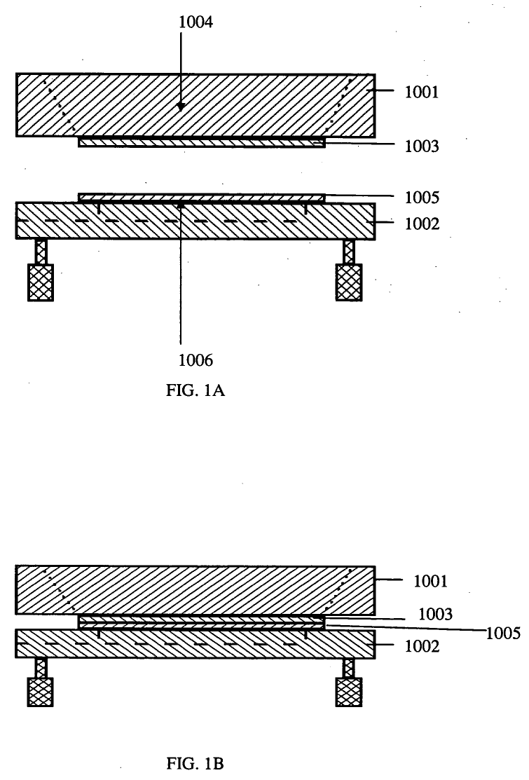

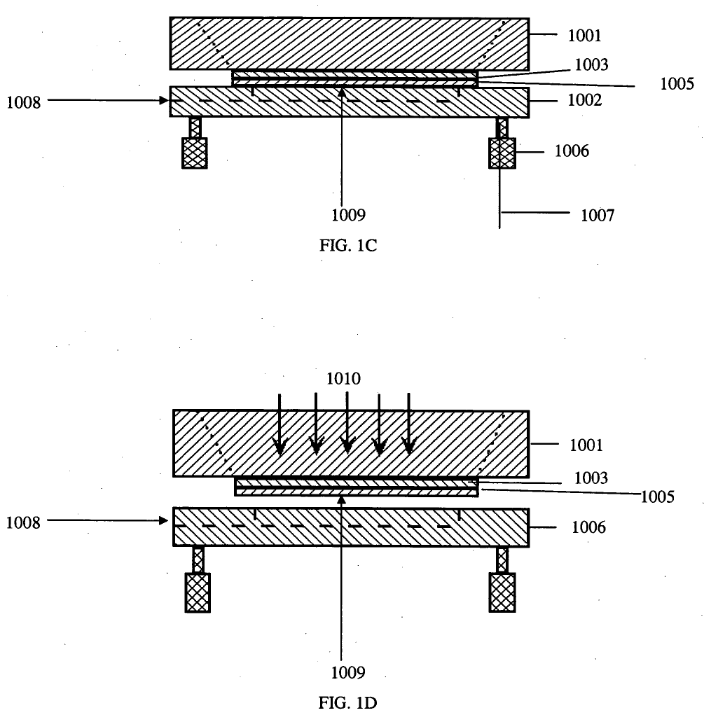

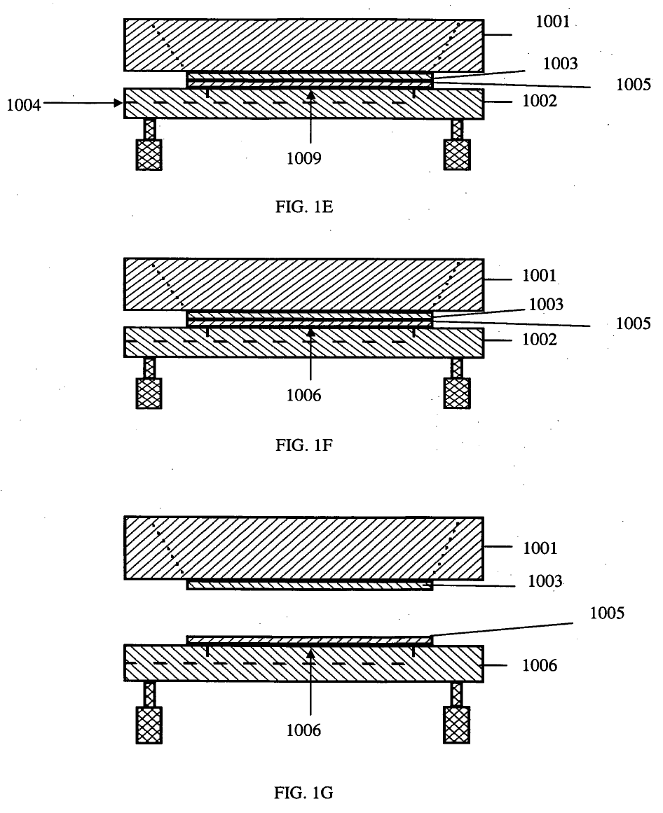

FIGS. 1A to 1G, according to an aspect of the present invention, display a step by step photolysis process in the fabrication of a synthesized wafer incorporating both the leveling and gas compressing methods. In one embodiment, the photolithography equipment is setup as shown in FIG. 1A. The upper chuck (1001) is in a fixed position while the lower chuck (1002) can be mechanically moved up or down. In this example, both the wafer (1005) and mask (1003) are held in position by vacuum (1004 & 1006) as shown in FIG. 1A. In FIG. 1B, the lower chuck (1002) mechanically moves up towards the upper chuck (1001) such that the wafer (1005) is juxtaposed and aligned with the mask (1003). Other photolithography configurations may have the mask or both the wafer and mask movable.

According to one aspect of the present invention, the leveling mechanism is performed after the mask and wafer are juxtaposed. Three mechanical axes (1006) move incrementally and apply force across the lower chuck (1002) which holds the wafer (1005) as shown in FIG. 1C. A plurality of sensors (1007) measures the force applied to the chuck (1002) from each axis (1006). These force measurements are then processed by a computer which then responds back by providing information to assist in the leveling of the substrate to the mask. The algorithm may include a plurality of feedback loops. The sensor (1007) may be any device that measures a mechanical load and sends a corresponding analog or digital signal to a computer or other control system. The leveling method can be used by itself to achieve a reduction of the gap between the wafer and the mask from the initial contact.

Since the surface of the mask and the surface of the wafer are not substantially flat, gaps are still formed even when applying a leveling method. In a preferred embodiment, the gap between the substrate and the mask can be further reduced by applying the gas compressing method. The leveling method facilitates the gas compressing method by having the wafer surface evenly spaced out across the surface of the mask before applying the compressed gas. Since the surface of the substrate is not perfectly flat, the application of the compressed gas to conform the wafer against the mask further reduces the gap between the wafer and the mask. In a preferred embodiment of the invention, a combination of both methods is used to provide the most reduction of light bleed-over.

In one embodiment of the present invention, components required for the gas compressing method are shown in FIG. 1C. A supply of compressed gas (1008) is used to compress the underside of the wafer (1005) against the mask (1003). This can be performed by replacing the vacuum that holds the substrate against the lower chuck with the compressed gas. Any gas can be used that is known in the art for example, air, clean dry air (CDA), argon, nitrogen, etc. In addition, liquid can be another way for applying force to the surface of the substrate to compress the substrate against the mask.

In another embodiment of the present invention, after the wafer (1005) is compressed against the mask by compressed gas, the lower chuck that was supporting the wafer is backed off a distance of approximately 5 μm to 100 μm (see FIG. 1D) from the mask (1003). The removal of the mechanical constraint allows a more uniform compression of the wafer against the mask.

According to another embodiment of the present invention, the lower chuck is backed off a distance of about 5 μm to 50 μm after the compressed gas is turned on to assist the substrate to conform to the mask. More preferably, the lower chuck is backed off a distance of about 10 μm to 20 μm, most preferably, 10 μm.

According to one aspect of the present invention, once the wafer is compressed against the mask, the wafer is exposed to a light (1010) to activate selected regions on the surface of the substrate. Specifically, functional groups on the surface of the substrate which are present in growing polymers are protected with photolabile protecting groups. Activation of selected regions of the substrate is carried out by exposing selected regions of the substrate surface to activation radiation, e.g., light within the effective wavelength range, as described previously. Selective exposure is typically carried out by shining a light source through a photolithographic mask onto the surface of a substrate while in contact.

The light source used for photolysis is selected to provide a wavelength of light that is photolytic to the particular protecting groups used, but which will not damage the forming polymer sequences. Typically, a light source which produces light in the UV range of the spectrum will be used. For example, in oligonucleotide synthesis, the light source typically provides light having a wavelength above 340 nm, to affect photolysis of the photolabile protecting groups without damaging the forming oligonucleotides. This light source is generally provided by a Hg-Arc lamp employing a 340 nm cut-off filter (i.e., passing light having a wavelength greater than 340-350 nm). Typical photolysis exposures are carried out at from about 6 to about 10 times the exposed half-life of the protecting group used, from about 8-10 times the half-life being preferred. For example, MeNPOC, a preferred photolabile protecting group, has an exposed half-life of approximately 6 seconds, which translates to an exposure time of approximately 36 to 60 seconds.

According to one aspect of the present invention, the steps used to remove the wafer from the chuck are shown in the following set of diagrams (see FIGS. 1E to 1G). As shown in FIG. 1E, the lower chuck (1002) moves back up in contact with the wafer (1005) and the vacuum (1006) is turned back on to hold the wafer against the lower chuck (1002) as shown in FIG. 1F. The chucks are then separated (refer to FIG. 1G) to transfer the exposed wafer (1005) from the photolysis equipment to the next step of the synthesis process.

Because the individual feature sizes on the surface of the substrate prepared according to the processes described herein can typically range from 1-10 μm, the effects of deflected, reflected or scattered light at the surface of the substrate can have significant effects upon the ability to expose and activate features of this size. The elimination or significant reduction of the gap between the wafer and mask assists in reducing the effects of the diffracted light during the photolysis step. The result is a much closer and more uniform contact between the mask and substrate, resulting in significant reduction in bleed-over and thus improved contrast. This provides the ability to print much smaller features on the substrate and thereby place many more features on a chip.

According to one aspect of the present invention, a method is provided for reducing bleed-over of light during fabrication of an array of polymers by transmitting light through a photolithographic mask having a first side and a second side. This mask is opaque to the transmission of light and has a plurality of apertures which are transparent with respect to the transmission of light. A substrate having a first side and a second side is provided. The light transmits through the mask via the apertures onto a substrate which also has a substantially flat solid support. The first side of the substrate has a plurality of features, where each feature has a pre-defined area on the substrate and has a plurality of reactive groups protected by photolabile protecting groups. The method then provides for the alignment of the apertures of the mask to the features on the support. The first side of the support is juxtaposed to the first side of the mask which creates a first gap having a distance between the mask and the first side of the support. The support is then compressed against the mask to form a second gap where the distance between the substrate and the mask is smaller than the first gap. A light of a predetermined wavelength is transmitted through the apertures of the mask to illuminate the features on the substrate.

According to another aspect of the present invention, the method further includes a coupling step. The substrate is coupled to the reactive groups with a monomer which has a reactive group protected by a photolabile protecting group. The aligning, juxtaposing, compressing, transmitting and coupling steps are repeated until the desired array is generated.

According to one aspect of the present invention, the substrate is a wafer. According to another aspect of the present invention, the pre-defined area of the feature is between 1 μm-10 μm. More preferably, the pre-defined area of the feature is between 3 μm-5 μm and most preferably, the feature is 5 μm. According to one aspect of the present invention, the feature and apertures are square. According to one aspect of the present invention, the first gap size is between 1 μm-50 μm. More preferably, the first gap size is between 5 μm-10 μm. Preferably the second gap size is between 0.1 μm-10 μm. More preferably, the second gap size is between 0.1 μm-5 μm and most preferably, the second gap size is 1 μm. According to one aspect of the present invention, the compressing step involves applying a compressed gas the surface of the substrate to create a gas pressure against said substrate surface. According to one aspect of the present invention, the gas pressure is between 5 psi-100 psi. More preferably, the gas pressure is between 70 psi-90 psi and most preferably, the gas pressure is 80 psi.

Preferably the array of polymers is an array of nucleic acids. More preferably, the array of nucleic acids is an array of oligonucleotides. The monomer is preferably a naturally or non-naturally occurring nucleotide. More preferably the nucleotide is selected from the group consisting of G, A, T, and C. In yet another preferred embodiment of the present invention, the array of polymers is an array of nucleotide analogs. In still another preferred embodiment of the present invention, the array of polymers is an array of peptides. Also, preferably, the monomer is an amino acid. It is also a preferred embodiment of the present invention that the amino acid is a naturally occurring amino acid or a non-naturally occurring amino acid.

According to one aspect of the present invention, the compressing step includes a leveling method which provides a first amount of force against the second side of the support to obtain equalized force measurements to a predetermined target value. The first set of force values is measured. After the measuring step, the algorithm is used to correct the first set of force measurements to equalize the first set of force measurements to a predetermined target value. A second amount of force determined by the algorithm is provided which is then applied against the second side of the support. The measuring, correcting and applying steps are repeated to obtain the equalized force measurements to a predetermined target value. According to one aspect of the present invention, the first amount of force is about 5 lbs and said first amount of force is between 1 lb-7 lbs and the second amount of force is from 5 to 6 lbs. Preferably, after repeating the leveling method, a force amount of approximately 5 lb+/−0.1 lb is obtained.

### EXAMPLES

### Example A

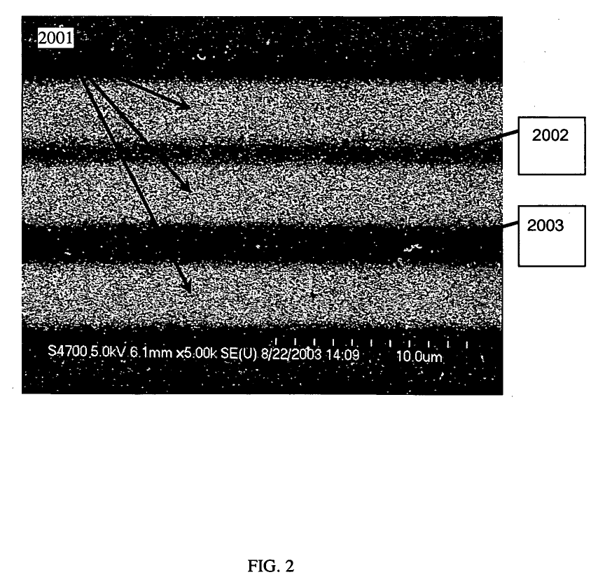

To provide higher photolithography resolution, the correlation of the print gap to the sharpness or contrast of the printed features was evaluated. Arrays were synthesized using the standard manufacturing procedures where the typical print gap, between the wafer and mask, ranged from 5 to 10 μm. A photo mask consisting of 3 μm bands with 1 μm lanes and 2 μm lanes were used to synthesize arrays. The SEM image of the hybridized synthesized wafer shows the patterns of the 3 μm bands (2001) with 1 μm lanes (2002) and 2 μm lanes (2003) as shown in FIG. 2. The edges of the 3 μm features (2001) appear to be “blurry” as a result of bleed-over from one feature to another. The bleed-over can be a result of divergence due to limited light collimation and light diffraction.

### Example B

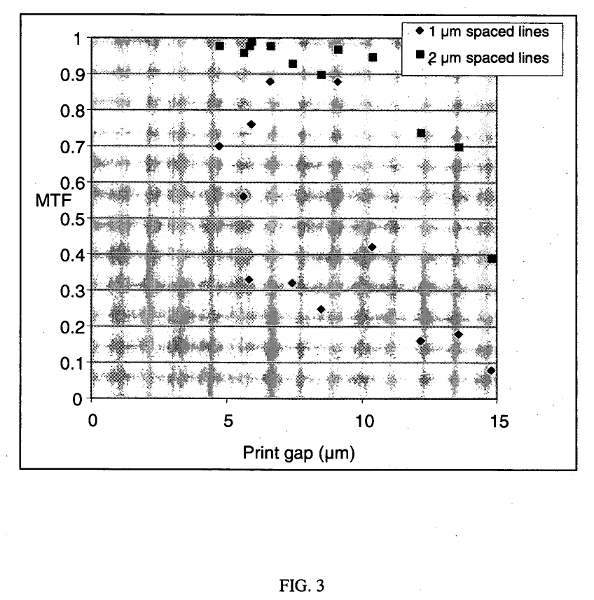

FIG. 3 displays a graphical representation of the modulation transfer functions (MTF) from the series of wafers that were synthesized at various print gaps. The MTF, a unit that characterizes the resolution or sharpness of the features, consists of the following equation: MTF=(P−V)/(P+V), where P stands for the peak and V stands for valley. The peak represents the highest intensity and the valley represents the lowest intensity of the area between the separated features. The MTF for each print gap was calculated and plotted. The MTF values for the 1 μm spacing are low relative to the 2 μm spacing which reflects the sharper edges observed with the 2 μm spacing in the SEM image. Ideally, the lowest intensity in the valley would be 0 and the MTF would then be equal to 1. This condition would be characterized by sharp edges. Based on this graph, the features increase in contrast as the print gap decreases. This correlation led to the idea of synthesizing wafers with as low a print gap as possible.

### Example C

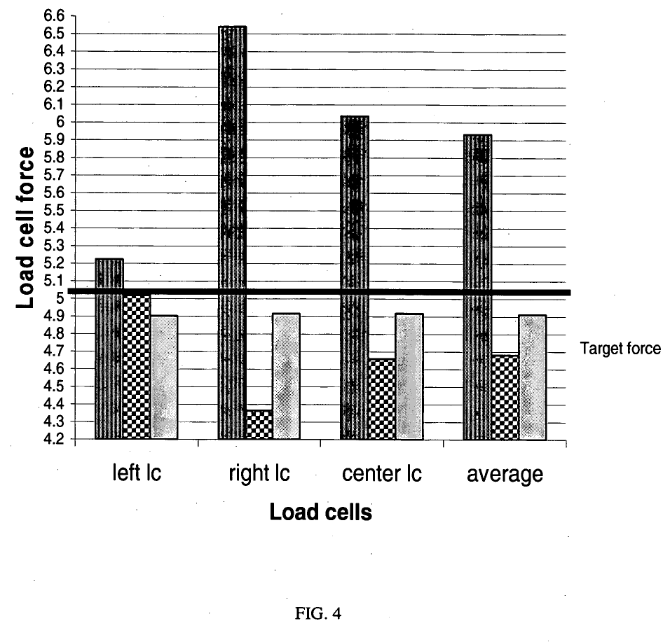

FIG. 4 shows the effects of a leveling method. The goal was to have all three load cells holding the wafer to the mask to be as close to 5 lbs and as evenly loaded as possible. As shown by the striped bars in FIG. 4, the resulting load cell forces varied between 5 to 7 lbs across the load cells of the wafers during the standard synthesis process. The checkered and solid bars represent load cell force results from synthesized wafers that incorporated various leveling methods. The checkerboard bars represent results from synthesized wafers that used a leveling method that included a simultaneous equation algorithm that brought the average closer to 5 lbs and the load cells force results more evenly distributed than performing the standard process. The solid bars represent results from wafers that were synthesized using an additional modification to the leveling method which was the addition of a trial and error or iterative algorithm. In general, the graph indicates that applying a leveling method improves the uniformity of the forces across the load cells.

### Example D

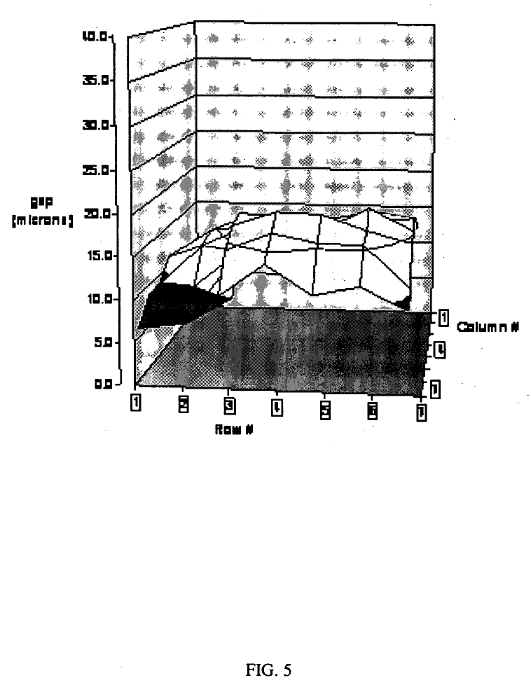

A 7×7 wafer (49 chips) was synthesized using the standard synthesis process. Gap measurements for each of the 49 chips were measured and plotted as displayed in FIG. 5 to show the profile of the wafer-mask gap across the entire surface of the wafer. Ideally, the profile would be flat and the print gap would be as close to 0 as possible.

### Example E

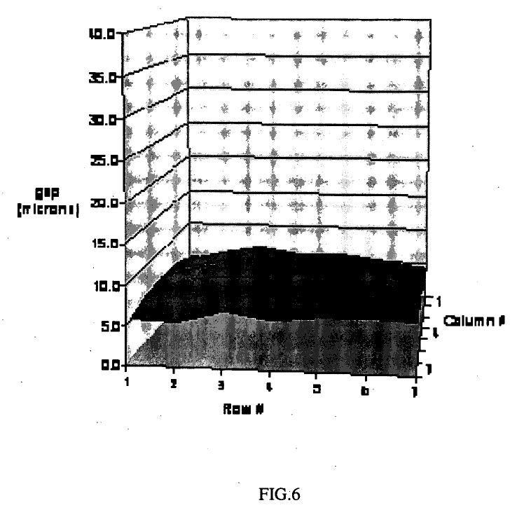

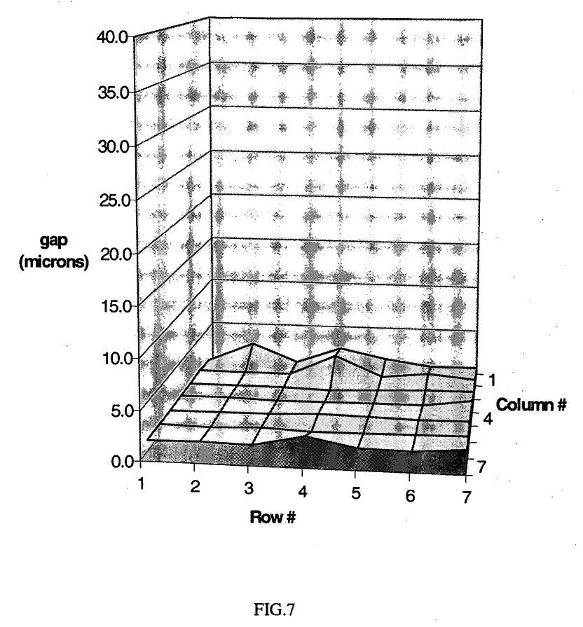

A lower, more uniform print gap across the wafer was observed when a leveling method was used to synthesize the wafer as shown in FIG. 6.

### Example F

Arrays were synthesized using the standard manufacturing procedure and both the leveling and gas compressing methods. A further improvement in the gap measurements was observed as shown in FIG. 7 and an average of 1 μm+/−0.5 μm gap across the wafer was achieved.

### Example G

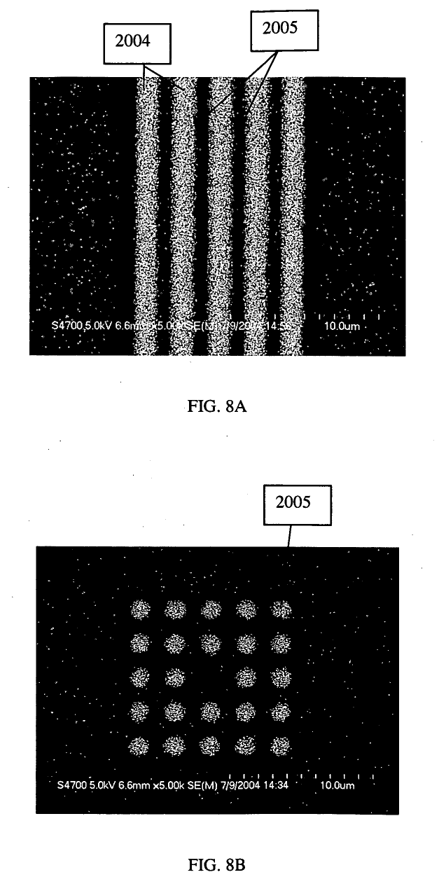

A photo mask including 1 μm bands with 1 μm lanes and 1 μm dots was used to synthesize arrays using the photolysis method with both the leveling and gas compressing methods. The SEM image of the hybridized synthesized array shows the patterns of the 1 μm bands (2004) and the 1 μm lanes (2005) as shown in FIG. 8A and him dots (2006) as shown in FIG. 8B. The edges of the 1 μm features (2004) and the 1 μm dots (2006) appear to be “sharp” as a result of improvement in the photolysis method.

It is understood that the examples and embodiments described herein are for illustrative purposes only and that various modifications or changes in light thereof will be suggested to persons skilled in the art and are to be included within the spirit and purview of this application and scope of the appended claims. All publications, patents, and patent applications cited herein are hereby incorporated by references for all purposes.

What is claimed is:

1. A method for reducing bleed-over of light during fabrication of an array of polymers by transmitting light through a photolithographic mask having a first side and a second side, wherein said mask is opaque to the transmission of light and has a plurality of apertures, wherein said apertures are transparent with respect to the transmission of light; said method comprising the steps of:
providing a substrate comprising a substantially flat solid support having a first side and a second side, wherein the first side of said support comprises a plurality of features, each said feature comprising a pre-defined area having a plurality of reactive groups, wherein each said group is protected by a photolabile protecting groups;
aligning the apertures of said mask with the features of said support;
juxtaposing said first side of said support to said mask, wherein said step of juxtaposing creates a first gap, having a distance between said mask and said substrate;
compressing said substrate against said mask wherein the distance between said substrate and said mask is reduced to form a second gap wherein said second gap is smaller than said first gap; and
transmitting light of a predetermined wavelength through said apertures of to remove said photolabile protecting group and to expose said plurality of reactive groups.

2. A method according to claim 1, wherein said substrate is a wafer.

3. A method according to claim 1, wherein said pre-defined area of said feature size is between 1 μm-10 μm.

4. A method according to claim 3, wherein said pre-defined area of said feature size is between 3 μm-5 μm.

5. A method according to claim 4, wherein said pre-defined area of said feature size is 5 μm.

6. A method according to claim 1, wherein said first gap size is between 1 μm-50 μm.

7. A method according to claim 6, wherein said first gap size is between 5 μm-10 μm.

8. A method according to claim 1, wherein said second gap size is between 0.1 μm-10 μm.

9. A method according to claim 8, wherein said second gap size is between 0.1 μm-5 μm.

10. A method according to claim 9, wherein said second gap size is 1 μm.

11. A method according to claim 1, wherein said compressing step further comprises the steps of:
providing a first amount of force against said second side of said support to obtain equalized force measurements to a predetermined target value;
measuring a first set of force measurements of said first amount of force;
correcting said first set of force measurements by using an algorithm that equalizes said first set of force measurements to said predetermined target value;
applying a second amount of force based on said correction step of said algorithm against said second side of said support to obtain a second set of force measurements; and
repeating said measuring, correcting and applying steps to obtain a final set of equalized force measurements to a final predetermined target value.

12. A method according to claim 11, wherein said predetermined target value is about 5 lbs.

13. A method according to claim 11, wherein said first amount of force is between 1-7 lbs.

14. A method according to claim 11, wherein said second amount of force is from 5 to 6 lbs.

15. A method according to claim 11, wherein said second amount of force after repeating said steps is about 5 lbs+/−0.1 lbs.

16. A method according to claim 1 further comprising the steps of:
coupling said exposed reactive group on said substrate with a monomer wherein said monomer comprises a reactive group protected by a photolabile protecting group; and
repeating said steps of aligning, juxtaposing, compressing, transmitting, and coupling until said desired array is generated.

17. A method according to claim 16, wherein said monomer is a nucleic acid.

18. A method according to claim 16, wherein said monomer is a nucleotide analog.

19. A method according to claim 16, wherein said monomer is an amino acid.

20. A method according to claim 16, wherein array of polymers is an array of nucleic acids.

21. A method according to claim 16, wherein said array of polymers is an array of oligonucleotides.

22. A method according to claim 1, wherein said compressing step comprises applying a compressed gas to said substrate to create a gas pressure against said substrate.

23. A method according to claim 22, wherein said gas pressure is 5 psi-100 psi.

24. A method according to claim 23, wherein said gas pressure is 70 psi-90 psi.

25. A method according to claim 24, wherein said gas pressure is 80 psi.
